(19) United States
(12) Patent Application Publication
(10) Pub. No.: US 2008/0049400 A1
(43) Pub. Date: Feb. 28, 2008

(54) Cover for a flat panel display

(76) Inventors: Philip Pecorino, Floral Park, NY (US); Aldo Medaglia, Rosyln, NY (US)

Correspondence Address: DARBY & DARBY P.C., P.O. BOX 770, Church Street Station, New York, NY, 10008-0770, US

(21) Appl. No.: 11/510,092

(22) Filed: Aug. 25, 2006

(51) Int. Cl. H05K 5/00

(52) U.S. Cl. 361/724

(57) ABSTRACT

The present invention provides a flat screen display cover for a video display unit that is mounted to a wall. In an illustrative embodiment, the cover unit includes a frame, a box-like extension located behind the frame, and a movable cover attached to a roller that is located within and supported by the extension. A motor unit located within the extension is operable to rotate the roller so that the movable cover acts to cover and uncover the display panel. A mat is disposed within the extension and supported between the movable cover and the display screen so that when the art cover is removed from in front of the video display screen, the user will not see a gap between the border of the screen and the art frame. Various size mats, or the cutting of various size openings in a mat, allow for a single-sized art frame to accommodate a variety of display screen sizes, as well as a variety of art print sizes.

### FIELD OF INVENTION

The present invention relates to a cover for a flat panel display, and in particular, to a an art cover unit for a flat panel display having a number of mat panels inserted between the art cover and the flat panel display such that when the art cover is removed, a clean appearance is provided, regardless of the size of the flat panel display.

### BACKGROUND OF THE INVENTION

The use of flat panel video displays, such as flat panel televisions, have become increasingly widespread. Flat panel televisions are becoming more and more affordable for consumers as the technology improves. In addition, the sizes of the displays of these flat panel televisions have increased significantly. As a result, more and more consumers are purchasing flat panel televisions of different sizes.

However, most consumers would prefer not to see a large grey box hanging on a wall of a bedroom, living room, or kitchen in their homes. It is also not practical for the consumer to have the flat panel television display a picture when the device is not being used, since this will significantly reduce the lifespan of the display unit. Therefore, it is desirable to cover the screen of the flat panel display with an aesthetically pleasing piece of artwork, such as a print or an embroidery, when the display unit is not in use, so as to conceal or disguise the display unit.

U.S. Pat. No. 5,264,765 (“the '765 patent”) describes a cover that can be placed over a video display screen to provide the consumer with a more aesthetically-pleasing look when the display screen is not in use. For example, a configuration according to the '765 patent includes a frame supporting an art canvas print, which conceals the flat screen video display. A motorized roller enables the art work to move upward to reveal the flat panel display and downward to cover it. A control for the motor may be activated by a remote control used to turn the flat panel display on and off.

However, it is burdensome for the consumer to obtain and install the cover described in the '765 patent. A consumer cannot walk into a retail store and purchase a display unit and an accompanying cover. Instead, the consumer must custom order the art print, as well as the art frame covering, based on the size of the display screen. Furthermore, the consumer must have the cover custom-installed by technicians who are skilled in both carpentry, and audio and video technology. This results in a very expensive and time consuming process for the consumer who wishes to use such a cover.

Thus, there is a need for an alternative which can provide the same aesthetically pleasing look while still being cost-effective and easy to use for consumers.

### SUMMARY OF THE INVENTION

The present invention is directed to a flat screen display cover unit that is a viable and cheaper alternative to the current expensive screen covers. In a preferred embodiment of the present invention, the display cover unit can be stocked in retail stores and sold directly to consumers. This allows the consumer to purchase a video display unit, along with a video display screen cover, at the same time.

In a preferred embodiment of the present invention, the display cover unit does not require custom installation, and thus, the display cover unit can be mounted concurrently when the video display unit is installed, for example, by a person of ordinary skill in the assembly and mounting of video display units. If the video display unit is already installed, the installation of the display cover unit of the present invention only requires a person to be capable of hanging a picture. Thus, in either scenario, the average consumer will be able to install the display cover unit of the present invention without having to hire installers or use expensive equipment.

In the preferred embodiment of the present invention, the flat panel video display is concealed by a display cover unit mounted on the same wall as the flat panel display. The display cover unit encases the flat panel video display so as to surround the front, top, bottom, and sides of the flat panel video display. The display cover unit includes an art frame at its front, and a flexible piece of artwork mounted on a roller behind the frame. The artwork can be rolled up, either manually or with a motor, to reveal the flat panel video display or rolled down to conceal the flat panel video display so that the flat panel video display appears to be only a piece of art hanging on the wall.

The frame of the display cover unit is attached to narrow top, bottom, and side support pieces having widths that are sufficient to hold the frame mechanisms and the flat panel video display. The rear portions of the top, bottom and side support pieces, which are remote from the frame, are adapted to fit flush against the wall upon which the flat panel video display is mounted. Mounting means are provided at the rear portions so as to mount the display cover unit to the wall. These may include a set of mounting fixtures, and the anchoring hardware.

The display cover unit may come in two or three sizes, each of which is intended to handle a range of flat panel video display sizes. In order to deal with the various possible sizes of the flat panel video display, the display cover unit is designed to accept a mat that is affixed to the display cover unit so that when the artwork is removed from view, the flat panel video display screen can be viewed without a gap between the border of the flat panel video display screen and the art frame. The display cover unit can either be provided with several mats having cutouts that match the sizes of flat panel video display screens for which the display cover unit is designed, or a single mat which can be cut to the appropriate size cutout for the flat panel video display screen. This allows for a single-sized display cover unit to accommodate a variety of flat panel video display screen sizes, as well as a variety of art print sizes.

### BRIEF DESCRIPTION OF THE DRAWINGS

Exemplary embodiments of the present inventions are explained in more detail below with reference to the accompanying drawings, in which:

FIG. 1A is an exploded view of the present invention according to a first embodiment;

FIG. 1B is an exploded view of the present invention according to a third embodiment;

FIG. 2A is a cross-sectional and broken view of the present invention according to the first embodiment;

FIG. 2B is a cross-sectional and broken view of the present invention according to a second embodiment;

FIG. 3A is a cross-sectional view of the present invention according to the third embodiment;

FIG. 3B is a cross-sectional view of the present invention according to a fourth embodiment;

FIG. 4A is an assembled view of the present invention without the mat; and

FIG. 4B is an assembled view of the present invention with the mat in place.

### DETAILED DESCRIPTION OF THE INVENTION

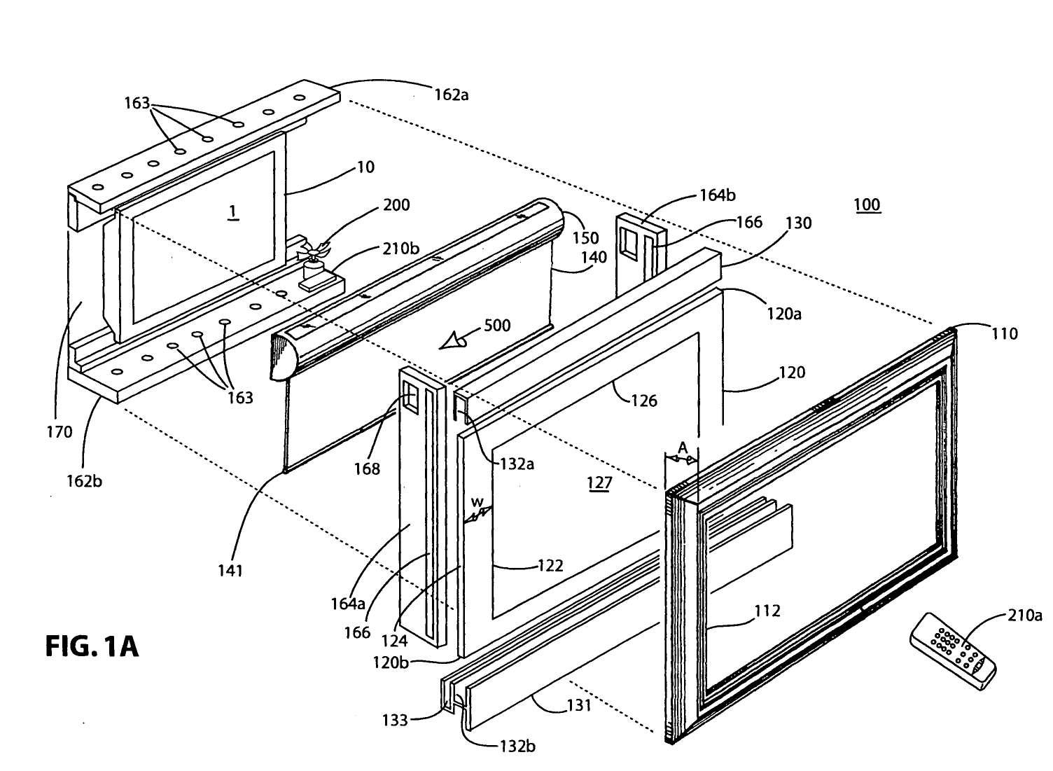

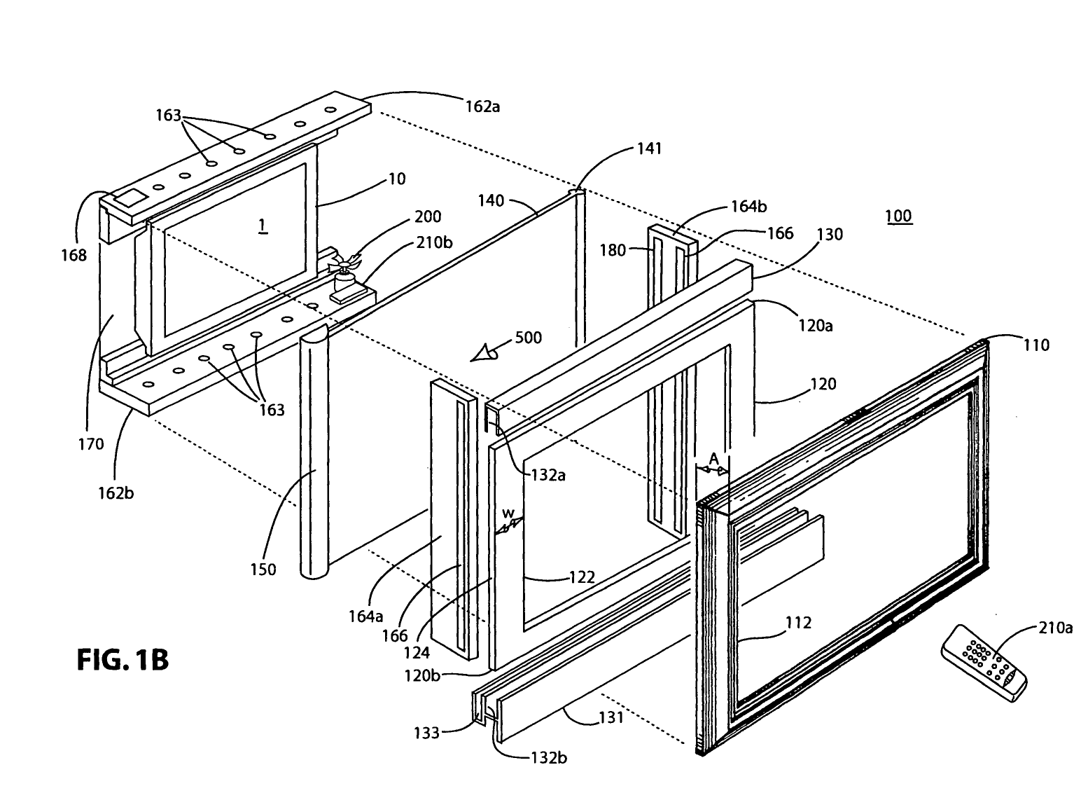

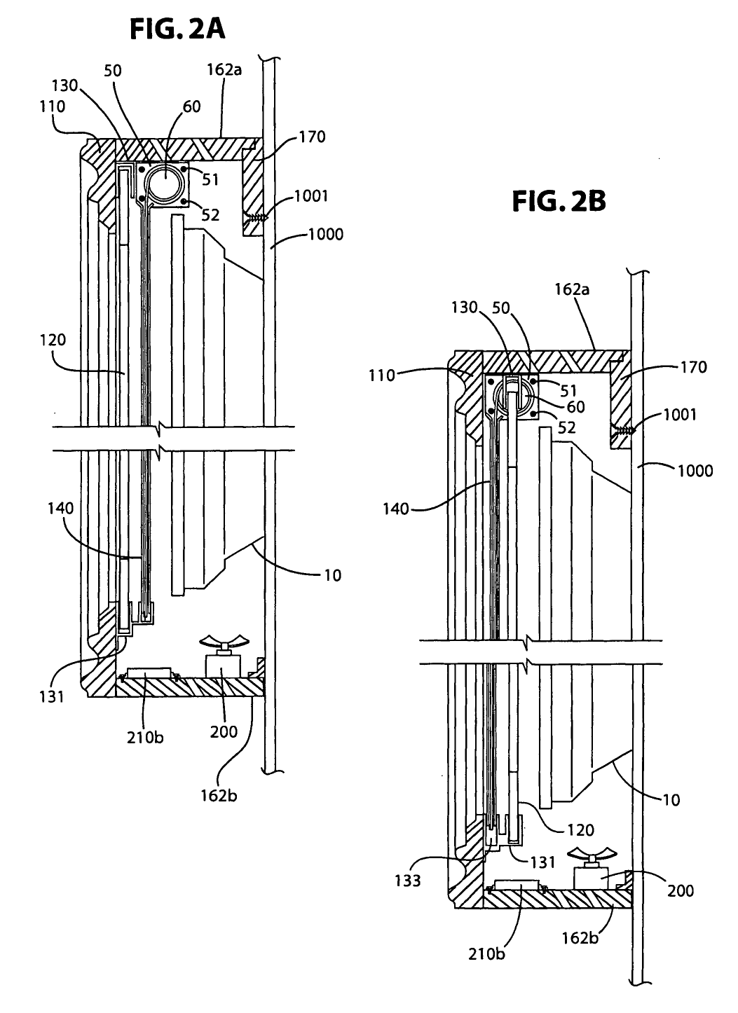

FIGS. 1A and 1B illustrate an embodiment of the present invention in which an art unit display cover 100 is shown in an exploded view. The art unit display cover 100 includes a frame 110, which is usually rectangular in shape, but can also have curved corners or edges or be in the shape of an oval or circle. The frame 110 is large enough to surround the perimeter of a flat panel video display 10. The frame 110 itself has sufficient depth A to accommodate the other elements of the display cover 100. Alternatively, the frame 100 has a box-like structure 160 which extends from the rear of the frame 110 to enclose the other elements of the display cover 100. This structure 160 includes top and bottom pieces 162a and 162b, as well as left and right side edges 164a and 164b. The structure 160 may also include a back surface 170 by means of which the entire art cover unit 100 is mounted to a wall 1000 via screws 1001, as shown in FIGS. 2A and 2B.

In FIGS. 1A and 1B, the flat panel video display screen 10 is illustratively shown as being mounted directly on the wall 1000, such as in the living room of a person's residence, for example. However, the flat panel video display screen 10 may also be mounted on an expandable swing arm bracket (not shown) so that during use, the screen 10 can be made to project through the frame and pivoted in one direction or the other. If such a bracket is to be used, the depth of the box-like structure 160 or the depth of the frame A may need to be increased. The signal and power wires (not shown) for the display screen 10 can be mounted behind or underneath the display screen 10 such that they are not visible to a viewer.

The art cover unit 100 also includes a fan 200 located on the bottom cover 162b, which helps to prevent the display screen 10 from overheating during use. Ventilation holes 163 are provided in the top 162a and bottom 162b to allow the fan 200 to be effective in cooling the display screen 10 when the display screen 10 is in use.

The art unit display cover 100 further includes a mat 120. The mat 120 may be cut to order, i.e., at the time of purchase or installation, to have an inside perimeter 122 that is of a desired size so as to match the outer perimeter of the display screen 10. To assist in cutting the mat or as a substitute therefore, the mat can be provided with score lines 126 that allow pieces of the mat of predetermined size to be broken off or cut off. The score lines will assist in making cleaner looking lines for the inner perimeter 122 of the mat.

As illustrated in FIG. 1A, the score lines 126 outline a “punch-out” 127 of the mat 120, which is removed during installation of the display cover 100. The outer perimeter 124 of the mat 120 extends to at least the inner perimeter 112 of the frame 110 so that the side edge of the mat 120 has a width W. The purpose of the mat 120 is to allow a single frame 110 to be used with various sizes of display screens which are smaller than the frame 110. FIG. 1B illustrates the mat 120 with the punch-out 127 having been removed.

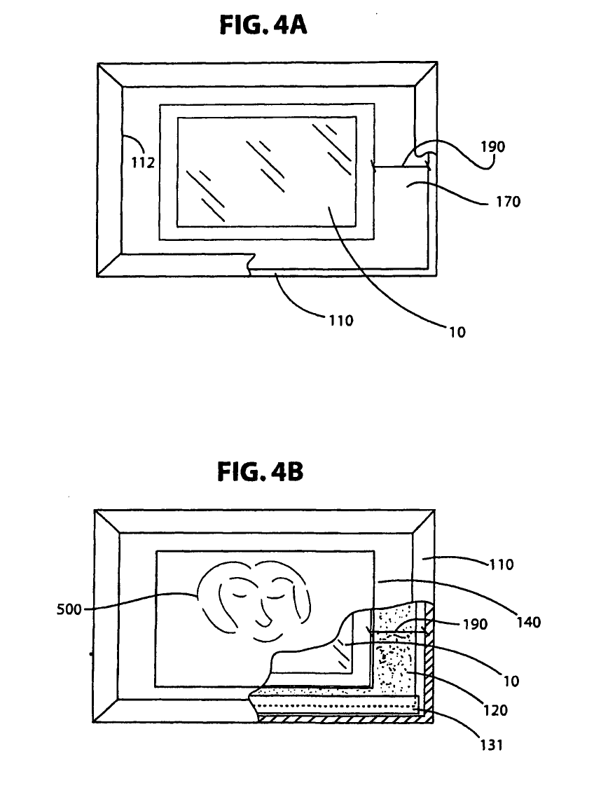

Traditionally, when viewing the display cover unit 100 used with a smaller flat panel video display, there will be a visible gap 190 between the extent of the screen or the outer edge of the display 10 and the inner perimeter 112 of the frame as show in FIG. 4A. As shown in FIG. 4A, when the display 10 is in use, the viewer will still be able to see the back surface 170 of the display cover unit 100.

The mat 120 of the present invention covers this gap 190 as shown in FIG. 4B. The mat 120 illustrated in FIG. 4B is adorned with a pattern so as to distinguish the mat 120 from the back surface 170 illustrated in FIG. 4A. It is to be understood that the mat 120 can have a variety of colors, textures, and/or patterns. Furthermore, although mat 120 is illustratively shown as being composed of a single piece of material, it can also be formed from several pieces which are pieced together to form the outer perimeter shape of mat 120.

The mat 120 is supported by a pair of guides 130, 131. The top guide 130 contains a track 132a that fits over the top surface edge 120a of mat 120. The bottom guide 131 contains a similar track 132b, which is correspondingly shaped to fit the bottom edge surface 120b of mat 120. The left panel 164a of the structure 160 has a closeable opening 166, which allows the mat 120 to be slid into the guides 130, 131 after having been cut to have the proper size opening (i.e., inner perimeter 122). Alternatively, instead of cutting the mat 120 to a specific size, because the mat 120 is inexpensive, a display cover unit 100 can be supplied with a plurality of mats 120 having a variety of sizes that fit a number of standard-sized display screens 10.

The art unit display cover 100 further includes a motorized screen 140, which is similar to that described in the '765 patent. The screen 140 supports the artwork 500, which can be an image, photo, drawing, sketch, painting, sewing embroidery, macramé, knitting, needlepoint, etc. The screen 140 is made of a canvas, print, or a flat flexible material of any composition that is suitable for supporting the artwork 500 and capable of being rolled.

In a first embodiment of the present invention illustrated in FIG. 1A, the screen 140 is attached at its top edge to a roller 60 that is driven by an optional motor 50. The motor 50 and roller 60 are housed within a motor unit 150, and are secured to the motor unit 150 via screws 51, 52. The motor 50 may be activated by a manual switch (not shown). Alternatively, the motor 50 can be activated by a remote control device 210a and corresponding receiver 210b, such as those used to control the display screen 10. The screen 140 can be raised or lowered by the motor 50 using any suitable system, such as a pulley or spring-loaded system. It is to be understood that the screen 140 can also be manually operated (i.e., without a motor), as will be apparent to those of ordinary skill in the art.

In the embodiment illustrated in FIG. 1A, the screen 140 is weighted on the bottom such that when it is fully deployed, the screen 140 rests in the guide 133. The weight 141 can be in the shape of a single rod, or it can be comprised of several individual weights that are sufficient for ensuring that the screen 140 will deploy in a suitable manner when the motor 50 is activated.

The roller 60 includes extensions at either end. One of the extensions fits in a socket of the motor 50 so that it can be turned. The other end (not shown) is rotatably supported in a bracket in the left side panel 164a. This allows the screen 140 to move in a manner similar to that of a window shade when activated by the motor 50 or when manually operated.

In a preferred embodiment of the present invention, the screen 140 is a removable cover, which allows the user to vary the artwork 500 of the display cover unit 100. Thus, if the user wishes to change the artwork 500, he or she would simply purchase a new screen 140 which has the desired new artwork 500. Alternatively, the artwork 500 may be attached to screen 140 by a releasable adhesive, so that it can be peeled off the screen 140 and replaced with another piece of artwork.

It is further possible to exchange the entire roller 60 with the screen 140 and artwork 500. To facilitate this, the left panel 164a is provided with a closeable opening 168 which provides access to a support bracket (not shown) for the extension of the roller 60. By removing the screws 51, the roller 60 can be released and dismounted from the bracket. As a result, the roller 60 can be slid out of the opening 168 once the screen 140 has been wound up on the roller 60. This is possible because the other side of the roller 60 has its extension or drive axle resting in the slot of the motor 50 and can be easily detached. The original roller 60 is then replaced with a new roller having a different screen and art work. The drive axle of the new roller can easily engage the drive slot in the motor. The front of the frame 110 is open so that the installer can see the slot and can guide the axle to the slot by extending his or her hand into the front of the frame 110.

FIG. 2A illustrates a first embodiment of the present invention. In this embodiment, the mat 120 is positioned in front of the artwork 500 located on the screen 140, as in the case with a traditional mat-and-frame arrangement. This layout is ideal for artwork that is best displayed using the traditional mat-and-frame arrangement.

When the screen 140 is removed from view by the motor 50 or by manual operation, the mat 120 remains positioned such that the viewer does not see any gaps between the outer perimeter of the display screen 10 and the frame 110. When the display screen 10 is in use, the mat 120 hides the back surface 170 and the wall 1000 on which the display screen 10 is mounted from the viewer's sight. When the display screen 10 is turned off and the screen 140 is activated so as to cover the display screen 10, the mat 120 provides a sufficient border between the artwork 500 and the frame 110.

Alternatively, as in a second embodiment illustrated in FIG. 2B, the mat 120 can be positioned behind the artwork 500 located on the screen 140. In the second embodiment, it is ideal for the artwork 500 to cover the entire screen 140 such that there is no need for a mat between the frame 110 and the artwork 500. In this embodiment, the mat 120 serves to frame the display screen 10 so as to cover the gap present between the inner perimeter 112 of the frame 110 and the outer perimeter of the display screen 10 and, thus, hide the back surface 170 and the wall 1000 from the viewer's sight.

In the embodiments illustrated in FIGS. 2A and 2B, the roller 60 and motor unit 150 are mounted on the top panel 162a of the art cover unit 100. Alternatively, the roller 60 and motor unit 150 can be mounted to the bottom panel 162b, with the screen 140 moving from bottom to top, as will be apparent to those of ordinary skill in the art. It is to be understood that the screen 140 can also be manually operated (i.e., without a motor), as will be apparent to those of ordinary skill in the art.

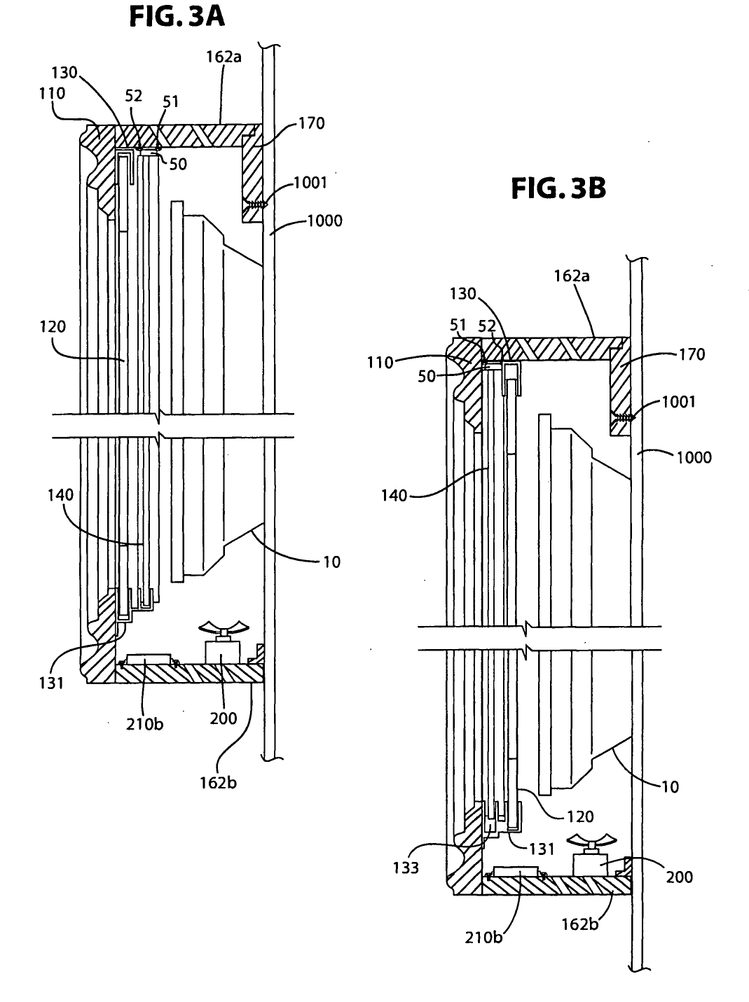

FIGS. 1B, 3A, and 3B illustrate a third and fourth embodiment of the present invention. In these embodiments, the roller 60 and motor unit 150 are mounted on the side of the display screen 10 and move the screen 140 in a horizontal fashion. Similar to the first and second embodiments of the present invention, the screen 140 of the third and fourth embodiments of the present invention can either be activated via a motor 50, or via manual operation without a motor.

FIG. 1B illustrates the side mount of the motor unit 150 in relation to the panels 164a, 164b. A securement 180 is positioned on the opposite side of the roller 60 and motor unit 150 such that when the flexible screen 140 is fully deployed across the display screen 10, the securement 180 attaches to the screen 140 to hold the screen 140 in place.

In the third and fourth embodiments of the present invention, the roller 60 can be removed via the opening 168. FIG. 1B illustrates the opening 168 being positioned on the top panel 162a. However, it is understood that the opening 168 can also be positioned on the bottom panel 162b, as is apparent to those of ordinary skill in the art. Furthermore, it is understood that although FIG. 1B illustrates the motor unit 150 mounted on the left side of the display cover unit 100, the motor unit 150, and correspondingly the opening 168, can be mounted on the right side of the display cover unit 100 such that the cover 140 moves from the right side of the screen 10 to the left side of the screen 10, as will be apparent to those of ordinary skill in the art.

As shown in FIG. 3A, in the third embodiment of the present invention, the screen 140 is mounted between the mat 120 and the display screen 10. Alternatively, in the fourth embodiment of the present invention as illustrated in FIG. 3B, the screen 140 can be mounted between the frame 110 and the mat 120. As discussed above with respect to the embodiments illustrated in FIGS. 2A and 2B, the third embodiment is ideal for use with artwork 500 that is best displayed in the traditional frame-and-mat arrangement, while the fourth embodiment is ideal for artwork 500 which does not require a mat 120 for display.

In the exemplary embodiment, the display cover unit 100 is designed to hold mats 120 of fixed outer dimensions. The mats 120 have viewing areas of various sizes with the dimensions and ratios that are similar to that of the display screen 10. Thus, the size W of the mat 120 can be varied by simply replacing the current mat 120 with replacement mats 120 having various viewing areas. This allows the user to vary the size of the display screen 10 without having to purchase and install an entirely new display cover unit 100.

Accordingly, the present invention provides a cost-effective solution for disguising a display screen having a variety of sizes, e.g., 30-inch, 40-inch, 50-inch, etc., using aesthetically-pleasing artwork that is provided on a cover. For example, the display cover unit 100 would be available in a number of fixed sizes, e.g., frame 110 is 40-inch, 60-inch, 80-inch, etc., in size. The art display cover unit 100 would also include a number of mats 120 in a variety of sizes, or the buyer could purchase different sized mats as needed.

Thus, if a person had a 30-inch display screen, the person would purchase a 40-inch art display cover unit and a 10-inch mat. If the same person later purchased a 35-inch display screen, he or she would be able to utilize the same 40-inch art display cover unit, and would simply only need to purchase a new mat 120.

Accordingly, instead of the user having to purchase a custom piece of artwork and a custom frame every time he or she wished to change display screens, the user can now purchase a single art display cover unit 100 and replace the mat 120 as needed. Further, there is no need to special order the display cover unit 100. The art display cover unit 100 can be sold at retail electronics stores along with the flat panel displays 10. Thus, the present invention provides a simple and more cost-effective solution for users to conceal display screens with aesthetically-pleasing artwork, while still providing the user with the flexibility changing the display screen as needed. Furthermore, users are given the ability to purchase the art display cover unit with the flat panel video display and to install the display cover unit with the flat panel video display without the need for custom ordering or installation.

While the invention has been particularly shown and described with reference to preferred embodiments thereof, it will be understood by those skilled in the art that various changes in form and details may be made therein without departing from the spirit and scope of the invention.

What is claimed is:

1. A cover unit for a display screen comprising:
a frame having a respective depth;
a movable cover positioned within the frame;
a mat disposed in the frame between the frame and the movable cover, said mat having an opening correspondingly-sized to hide a gap between the frame and the display screen; and
a unit located within the frame and operable to move the movable cover to cover and uncover the display panel.

2. The cover unit according to claim 1, wherein the mat is interchangeable with a variety of other mats.

3. The cover unit according to claim 1, wherein the unit is a motor that moves the cover in a vertical direction.

4. The cover unit according to claim 1, wherein the unit is a motor that moves the cover in a horizontal direction.

5. The cover unit according to claim 1, further comprising:
a roller; and
a motor attached to the roller and operable to rotate the roller,
wherein the cover is attached to the roller so that the cover is unrolled from and rolled onto the roller as is the roller is rotated by the motor.

6. The cover unit according to claim 1, wherein the movable cover is interchangeable with a variety of other moveable covers.

7. The cover unit according to claim 3, wherein the movable cover further comprises:
a free edge opposite an edge attached to the motor; and
a weight attached to the free edge of the movable cover.

8. The cover unit according to claim 1 wherein the frame further comprises:
a front frame part; and
a box-like extension to provide depth for the cover, mat and unit.

9. The cover unit according to claim 4, further comprising:
a securement which secures the movable cover when the movable cover has been fully deployed.

10. A cover unit for a display screen comprising:
a frame;
a movable cover located within and supported by the extension;
a mat disposed between the movable cover and the display screen, the mat having a opening correspondingly-sized to hide a gap between the frame and the display screen; and
a motor unit operable to move the movable cover to cover and uncover the display panel.

11. The cover unit according to claim 10, wherein the mat is interchangeable with a variety of other mats.

12. The cover unit according to claim 10, wherein the motor unit moves the cover in a vertical direction.

13. The cover unit according to claim 10, wherein the motor unit moves the cover in a horizontal direction.

14. The cover unit according to claim 10, further comprising:
a roller rotated by the motor unit; and
the cover further comprising a first edge attached to the roller,
wherein the cover is rolled onto and unrolled from the roller as the roller is rotated by the motor.

15. The cover unit according to claim 10, wherein the movable cover is interchangeable with a variety of other moveable covers.

16. The cover unit according to claim 12, wherein the movable cover further comprises:
a free edge opposite an edge attached to the motor; and
a weight attached to the free edge of the movable cover.

17. The cover unit according to claim 13, further comprising:
a securement for securing the movable cover when the movable cover has been fully deployed.

18. The cover unit according to claim 10 wherein the frame further comprises:
a front frame part; and
a box-like extension to provide depth for the cover, mat and unit.

19. A cover unit for a display screen comprising:
a frame;
a movable cover;
a mat having an opening correspondingly-sized to hide a gap between the frame and the display screen; and
a motor unit operable to move the movable cover to cover and uncover the display panel.

20. The cover unit according to claim 20 further comprising:
a remote control for the display screen; and
a motor controller operable to control the deployment of the cover.
